(19) United States
(12) Patent Application Publication
(10) Pub. No.: US 2020/0142262 A1
(43) Pub. Date: May 7, 2020

(54) DISPLAY APPARATUS

(71) Applicant: Samsung Display Co., Ltd., Yongin-Si (KR)

(72) Inventors: Mingyeong SHIN, Hwaseong-si (KR); Donghwan KIM, Hwaseong-si (KR); Haechan PARK, Seoul (KR)

(21) Appl. No.: 16/509,266

(22) Filed: Jul. 11, 2019

(30) Foreign Application Priority Data
Nov. 1, 2018 (KR) 10-2018-0133053

(51) Int. Cl. G02F 1/1343; H01L 27/12; G02F 1/1368; G02F 1/1362; G02F 1/1337

(52) U.S. Cl. CPC G02F 1/134309; H01L 27/124; G02F 1/1368; G02F 2001/133742; G02F 1/13624; G02F 1/1337; G02F 1/136286

(57) ABSTRACT

A display apparatus includes a data line extending in a first direction, a gate line extending in a second direction, a first pixel circuit connected to the data line and the gate line, a first pixel electrode connected to the first pixel circuit to receive a first pixel voltage and disposed in a first pixel area, a second pixel electrode connected to the second pixel circuit to receive a second pixel voltage and disposed in a second pixel area, a second pixel circuit connected to the data line and the gate line, and a pixel electrode bar. The second pixel voltage is higher than the first pixel voltage. The second pixel electrode is adjacent to the first pixel electrode in the first direction. The pixel electrode bar branches from the first pixel electrode and extends in the first direction and disposed adjacent to the first electrode and the second pixel electrode.

### CROSS-REFERENCE TO RELATED APPLICATIONS

This U.S. non-provisional patent application claims priority under 35 U.S.C. § 119 to Korean Patent Application No. 10-2018-0133053, filed on Nov. 1, 2018, the disclosure of which is hereby incorporated by reference in its entirety.

### BACKGROUND

The present disclosure relates to a display apparatus. More particularly, the present disclosure relates to a display apparatus operating in a vertically aligned mode.

A liquid crystal display device includes a liquid crystal display panel that includes two substrates facing each other and a liquid crystal layer disposed between the two substrates. When a voltage is applied to an electric field generating electrode, an electric field is applied to the liquid crystal layer to determine an alignment direction of liquid crystal molecules of the liquid crystal layer, and an image is displayed by controlling polarization of an incident light.

Among various types of liquid crystal display devices, a vertically aligned mode liquid crystal display device refers to a liquid crystal display device in which the long axis of liquid crystal molecules is arranged to be perpendicular to two substrates in a state in which no electric field is applied. The vertically aligned mode liquid crystal display device has a large contrast ratio and is capable of easily implementing a wide reference viewing angle.

To improve a viewing angle characteristic of a liquid crystal display device, techniques for dividing and controlling a pixel area into a plurality of domains have been developed, and examples of such techniques include a charge share (CS) method and a resistivity division (RD) method.

Those techniques to improve a viewing angle characteristic using a plurality of domains as described above require multiple transistors and multiple capacitors, so the transmittance of the liquid crystal display panel may be adversely reduced.

### SUMMARY

The present disclosure provides a display apparatus having improved transmittance and visibility.

An embodiment of the inventive concept provides a display apparatus including a data line extending in a first direction; a gate line extending in a second direction; a first pixel circuit connected to the data line and the gate line; a first pixel electrode connected to the first pixel circuit to receive a first pixel voltage and disposed in a first pixel area; a second pixel circuit connected to the data line and the gate line; a second pixel electrode connected to the second pixel circuit to receive a second pixel voltage that is higher than the first pixel voltage and disposed in a second pixel area so as to be adjacent to the first pixel electrode in the first direction; and a pixel electrode bar branching from the first pixel electrode and extending in the first direction and disposed adjacent to the first pixel electrode and the second pixel electrode.

In an embodiment, the first pixel electrode may include a first trunk including a first horizontal trunk extending in the second direction and a first vertical trunk extending in the first direction to divide the first pixel area into a plurality of domains; and a plurality of first branches radially extending from the first trunk.

In an embodiment, the pixel electrode bar may extend from the first horizontal trunk that extends in the first direction.

In an embodiment, the pixel electrode bar may include a first pixel electrode bar extending from a first end of the first horizontal trunk and a second pixel electrode bar extending from a second end of the first horizontal trunk.

In an embodiment, the second pixel electrode may include a second trunk including a second horizontal trunk extending in the second direction and a second vertical trunk extending in the first direction to divide the second pixel area into a plurality of domains; and a plurality of second branches radially extending from the second trunk.

In an embodiment, the display apparatus of the present disclosure may further include a plurality of protrusions protruding from a portion of the pixel electrode bar adjacent to the second pixel area toward the plurality of second branches of the second pixel electrode.

In an embodiment, the plurality of second branches may obliquely extend at a first angle from the second trunk, and the plurality of protrusions may obliquely protrude at a second angle from the pixel electrode bar.

In an embodiment, the absolute magnitudes of the first angle and the second angle may be the same.

In an embodiment, each of the plurality of second branches may include one or more sub-branches having end surfaces partially facing end surfaces of the plurality of protrusions.

In an embodiment, each of the plurality of second branches may include one or more sub-branches shifted in the first direction or a third direction that is opposite to the first direction from end surfaces of the plurality of protrusions and having end surfaces partially facing end surfaces of the plurality of protrusions.

In an embodiment, the display apparatus of the present disclosure may further include a first protrusion protruding from a first portion of the first pixel electrode bar toward the plurality of second branches of the second pixel electrode; and a second protrusion protruding from a second portion of the second pixel electrode bar toward the plurality of second branches of the second pixel electrode.

In an embodiment, the plurality of second branches may obliquely extend at a first angle from the second trunk, and the first protrusions may include a first sub-protrusion obliquely protruding at a second angle with respect to a virtual line that is parallel to the second horizontal trunk; and a second sub-protrusion obliquely protruding at a third angle with respect to the virtual line.

In an embodiment, the first sub-protrusion may be inclined at a positive angle with respect to the virtual line, and the second sub-protrusion may be inclined at a negative angle with respect to the virtual line, and absolute magnitudes of the first angle, the second angle, and the third angle may be the same.

In an embodiment, the plurality of second branches may obliquely extend at a first angle from the second trunk, and the second protrusions may include a third sub-protrusion obliquely protruding at a second angle with respect to a virtual line that is parallel to the second horizontal trunk; and a fourth sub-protrusion obliquely protruding at a third angle with respect to the virtual line.

In an embodiment, the third sub-protrusion may be inclined at a positive angle with respect to the virtual line, and the fourth sub-protrusion may be inclined at a negative angle with respect to the virtual line, and the absolute magnitudes of the first angle, the second angle, and the third angle may be the same.

In an embodiment, the display apparatus of the present disclosure may further include a third protrusion protruding from a third portion of the first pixel electrode bar toward the plurality of first branches of the first pixel electrode; and a fourth protrusion protruding from a fourth portion of the second pixel electrode bar toward the plurality of first branches of the first pixel electrode.

In an embodiment, a protrusion length of each of the third protrusion and the fourth protrusion may be smaller than a protrusion length of each of the first protrusion and the second protrusion.

In an embodiment, the first pixel circuit may include a first transistor including a first control electrode connected to the gate line, a first input electrode connected to the data line, and a first output electrode connected to the first pixel electrode; and a second transistor including a second control electrode connected to the gate line, a second input electrode receiving a storage voltage, and a second output electrode connected to the first output electrode of the first transistor.

In an embodiment, the second pixel circuit may include a third transistor including a third control electrode connected to the gate line, a third input electrode connected to the data line, and a third output electrode connected to the second pixel electrode.

In an embodiment, when a data voltage applied to the data line is in a first voltage range, the first pixel voltage may maintain a black gray level, a non-transmissive region is formed in a region in which the pixel electrode bar is formed, and liquid crystal molecules in the non-transmissive region are vertically aligned to block light.

In an embodiment, when the data voltage is in a second voltage range that is higher than the first voltage range, a transmissive region is formed between the pixel electrode bar and the second pixel electrode, and the liquid crystal molecules in the transmissive region are aligned to transmit light.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view showing an exemplary embodiment of a display apparatus according to the present disclosure;

FIG. 2 exemplarily shows a block diagram of the display apparatus shown in FIG. 1;

FIG. 3 exemplarily shows an equivalent circuit diagram of a pixel among the pixels shown in FIG. 2;

FIG. 4 is a graph showing the transmittance according to voltages of first and second pixels shown in FIG. 3;

FIG. 5 is a plan view showing a layout of pixels according to an embodiment of the present disclosure;

FIG. 6 is a sectional view taken along line I-I′ shown in FIG. 5;

FIG. 7 is a plan view showing a pixel electrode layer shown in FIG. 5;

FIG. 8A and FIG. 8B are enlarged views of each of the portions II and III of FIG. 7;

FIG. 9 is a plan view showing another exemplary embodiment of a pixel electrode bar according to the present disclosure;

FIG. 10A and FIG. 10B are enlarged views of each of the portions IV and V of FIG. 9;

FIG. 11A is a view showing a simulation result of a liquid crystal array in a structure in which a shielding electrode is disposed as a comparative example;

FIG. 11B is a view showing a simulation result of a liquid crystal array in a structure in which a pixel electrode bar according to the present disclosure is disposed;

FIG. 12 is a plan view showing another exemplary embodiment of a pixel electrode bar according to the present disclosure; and

FIG. 13A and FIG. 13B are enlarged views of each of the portions VI and VII of FIG. 12.

### DETAILED DESCRIPTION

In the present disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. In addition, in the drawings, a thickness, a ratio, and a dimension of elements may be exaggerated for effective illustration and description thereof.

The term “and/or” includes any or all combinations of one or more of associated elements or configurations may define.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the inventive concept. The terms of a singular form may include a plural form unless the context clearly indicates otherwise.

In addition, terms such as “below,” “lower,” “above,” “upper,” and the like are used to describe a relative relationship of the configurations shown in the drawings. The terms are used as a relative concept and are described with reference to an orientation or a direction indicated in the drawings.

It should be understood that the terms “comprise” or “have” are intended to specify a presence of stated features, integers, steps, operations, elements, components, or combinations thereof in the present disclosure, but do not preclude a presence or an addition of one or more other features, integers, steps, operations, elements, components, or combinations thereof.

Hereinafter, exemplary embodiments of the inventive concept will be described with reference to the accompanying drawings.

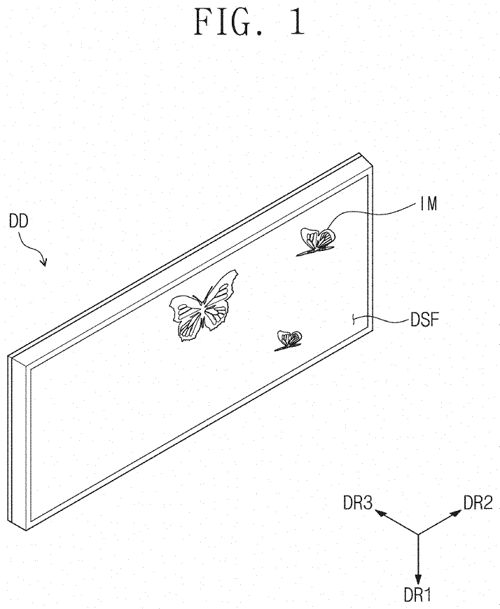

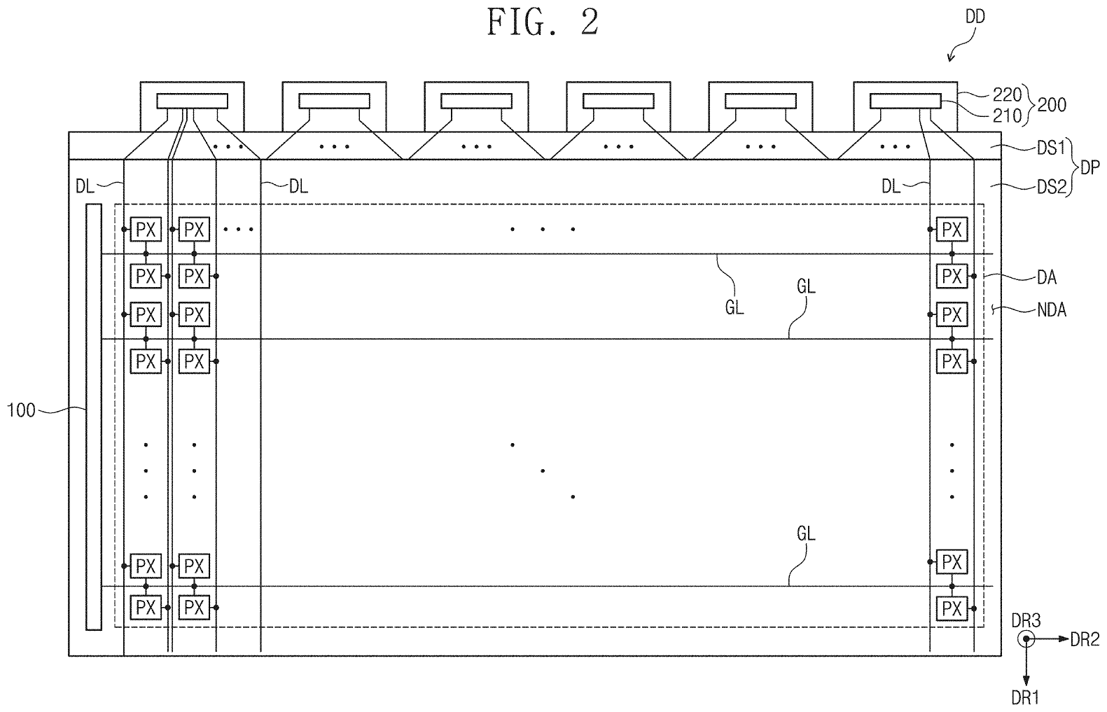

FIG. 1 is a perspective view showing an exemplary embodiment of a display apparatus according to the inventive concept. FIG. 2 exemplarily shows a block diagram of the display apparatus shown in FIG. 1.

Referring to FIG. 1, a display apparatus DD may provide an image IM to a user through a display surface DSF. In the present specification, a butterfly is illustrated as an example of the image IM. The display surface DSF may be parallel to a plane defined by a first direction DR1 and a second direction DR2. A third direction DR3 is perpendicular to the plane defined by the first direction DR1 and the second direction DR2.

Referring to FIG. 2, the display apparatus DD according to an embodiment of the inventive concept includes a display panel DP, a gate driving circuit 100, and a data driving circuit 200.

The display panel DP is not particularly limited, and for example, may include various display panels such as a liquid crystal display panel, an organic light emitting display panel, an electrophoretic display panel, and an electrowetting display panel. In the present embodiment, a liquid crystal display panel is shown as an example of the display panel DP. Meanwhile, a liquid crystal display device including the liquid crystal display panel may further include a polarizing member or a backlight unit and the like, which are not shown in FIG. 2.

The display panel DP includes a first substrate DS1, a second substrate DS2 that is spaced apart from the first substrate DS1, and a liquid crystal layer (not shown) disposed between the first substrate DS1 and the second substrate DS2. On a plane, the display panel DP includes a display area DA on which a plurality of pixels PX are disposed, and a non-display area NDA surrounding the display area DA. The display surface DSF shown in FIG. 1 may correspond to the display area DA.

The display panel DP includes a plurality of gate lines GL disposed on the first substrate DS1 and a plurality of data lines DL crossing the gate lines GL. The plurality of gate lines GL is connected to the gate driving circuit 100. The plurality of data lines DL is connected to the data driving circuit 200.

In FIG. 2, portions of a plurality of pixels PX are shown. Each of the plurality of pixels PX is respectively connected to a corresponding gate line among the plurality of gate lines GL and a corresponding data line among the plurality of data lines DL.

Each of the plurality of pixels PX may display one of primary colors. The primary colors may include red, green, blue, and white. However, the inventive concept of the present disclosure is not limited thereto, and the plurality of pixels PX may display one of mixed colors. The mixed colors may further include various colors such as yellow, cyan, and magenta.

The gate driving circuit 100 generates gate signals and outputs the generated gate signals to the gate lines GL.

In FIG. 2, one gate driving circuit 100 that is connected to left ends of the plurality of gate lines GL is exemplarily shown. However, the number of the gate driving circuit 100 and its disposed position are not limited thereto. For example, the display apparatus DD may include two gate driving circuits respectively connected to left and right ends of the plurality of gate lines GL.

The data driving circuit 200 generates data signals according to received image data. The data driving circuit 200 outputs the generated data signals to the plurality of data lines DL. In the present disclosure, a data signal may also be referred to as a data voltage.

The data driving circuit 200 may include a data driver 210 and a flexible circuit board 220 on which the data driver 210 is mounted. The data driver 210 and the flexible circuit board 220 may be provided in plurality.

Each of the plurality of data drivers 210 provides corresponding data signals to corresponding data lines DL among the plurality of data lines DL.

In FIG. 2, the data driving circuit 200 provided by the chip on film (COF) method is exemplarily shown. In another embodiment of the inventive concept, the data driver 210 may be disposed in the non-display area NDA of the display panel DP by the chip on glass (COG) method.

Referring to FIG. 2, the pixels PX are arranged in a matrix form to form a plurality of pixel rows and a plurality of pixel columns. The pixels PX included in each of the pixel rows are arranged in the first direction DR1. The pixel rows are arranged in the second direction DR2. The pixels PX included in each of the pixel columns are arranged in the second direction DR2. The pixel columns are arranged in the first direction DR1.

According to one embodiment, each of the pixel columns may be connected to two data lines DL. Specifically, one of the two data lines DL may be connected to odd-numbered pixels among the pixels PX in the pixel column, and the other of the two data lines DL may be connected to the even-numbered pixels among the pixels PX in the pixel column. In addition, two adjacent pixel rows among the plurality of pixel rows may be connected to one gate line GL.

In the embodiment shown in FIG. 2, the display apparatus DD may be configured to have the gate lines GL half the number of pixel rows. Accordingly, when compared with other embodiments in which the gate lines GL are provided in the same number as the number of pixel rows, time for applying a gate signal may be increased. This is advantageous because the accuracy of the gate signal applied to a pixel can increase, and the gate signal can be stably applied to the pixel particularly when the display panel DP has a high-resolution.

However, the inventive concept of the present disclosure is not limited thereto. In another embodiment of the inventive concept, each of the pixel columns may be connected to one corresponding date line DL, and each of the pixel rows may be connected to one corresponding gate line GL.

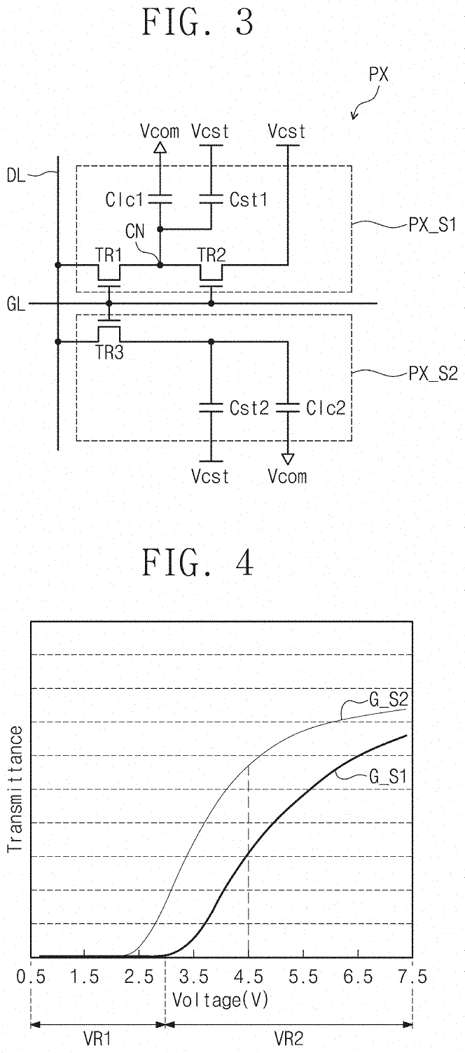

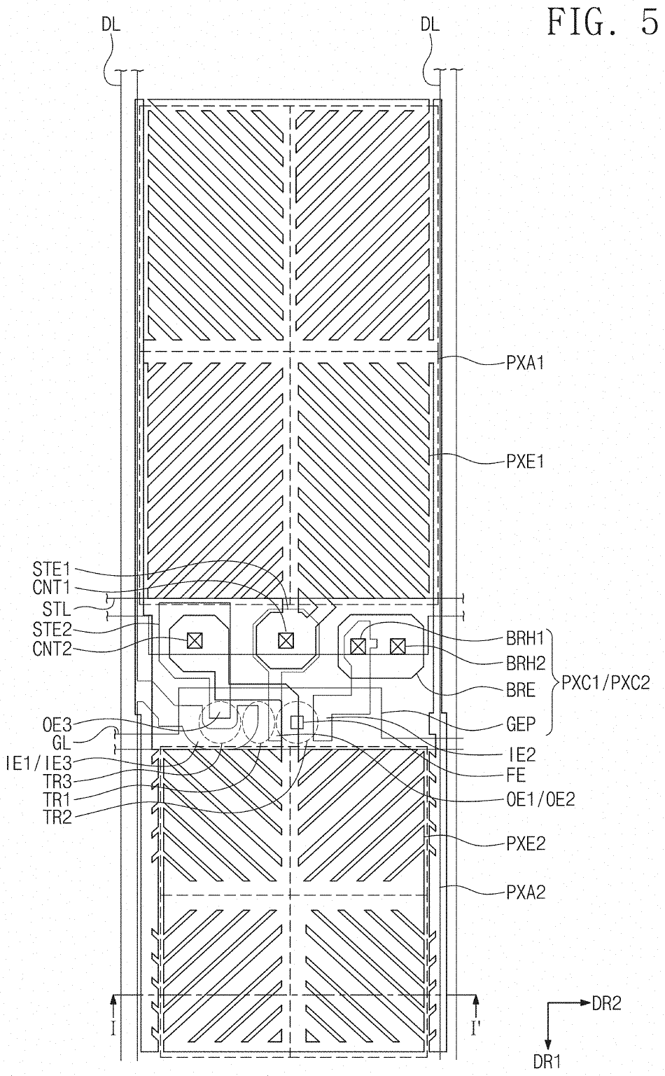

FIG. 3 exemplarily shows an equivalent circuit diagram of a pixel among the pixels PX shown in FIG. 2. FIG. 4 is a graph showing the transmittance according to voltages of first and second pixels shown in FIG. 3.

Since the pixels PX shown in FIG. 2 have the same structure, one pixel will be described with reference to FIG. 3, and a detailed description of remaining pixels will be omitted.

Referring to FIG. 3, the pixel PX may include a first sub-pixel PX S1 and a second sub-pixel PX S2.

The first sub-pixel PX S1 may include a first transistor TR1, a second transistor TR2, a first liquid crystal capacitor Clc1, and a first storage capacitor Cst1. The second sub-pixel PX S2 may include a third transistor TR3, a second liquid crystal capacitor Clc2, and a second storage capacitor Cst2.

A control electrode of the first transistor TR1 is connected to the gate line GL, an input electrode of the first transistor TR1 is connected to the data line DL, and an output electrode of the first transistor TR1 is connected to the first liquid crystal capacitor Clc1 and the first storage capacitor Cst1.

A first electrode of the first liquid crystal capacitor Clc1 is connected to the output electrode of the first transistor TR1, and a second electrode of the first liquid crystal capacitor Clc1 receives a common voltage Vcom. A first electrode of the first storage capacitor Cst1 is connected to the output electrode of the first transistor TR1, and a second electrode of the first storage capacitor Cst1 receives a storage voltage Vcst.

A control electrode of the second transistor TR2 is connected to the gate line GL, an input electrode of the second transistor TR2 receives the storage voltage Vcst, and an output electrode of the second transistor TR2 is connected to the output electrode of the first transistor TR1.

A control electrode of the third transistor TR3 is connected to the gate line GL, an input electrode of the third transistor TR3 is connected to the data line DL, and an output electrode of the third transistor TR3 is connected to the second liquid crystal capacitor Clc2 and the second storage capacitor Cst2.

A first electrode of the second liquid crystal capacitor Clc2 is connected to the output electrode of the third transistor TR3, and a second electrode of the second liquid crystal capacitor Clc2 receives the common voltage Vcom. A first electrode of the second storage capacitor Cst2 is connected to the output electrode of the first transistor TR3, and a second electrode of the second storage capacitor Cst2 receives the storage voltage Vcst.

According to one embodiment, the common voltage Vcom and the storage voltage Vcst may have substantially the same voltage level.

The first to third transistors TR1, TR2, and TR3 may be simultaneously turned on by a gate signal provided through the gate line GL.

A data voltage of the data line DL is provided to the first sub-pixel PX S1 when the first transistor TR1 is turned on. In addition, the storage voltage Vcst is provided to the first sub-pixel PX S1 when the second transistor TR2 is turned on.

A voltage at a contact node CN to which the first transistor TR1 and the second transistor TR2 are connected (hereinafter referred to as a divided voltage) has a value that is a fraction of the data voltage of the data line DL that is determined based on a ratio of resistance values across the first and second transistors TR1 and TR2 when both of the first and second transistors TR1 and TR2 are turned on. That is, when both of the first and second transistors TR1 and TR2 are turned on, the divided voltage has a value between the data voltage of the data line DL provided through the first transistor TR1 and the storage voltage Vcst provided through the second transistor TR2.

Accordingly, the first liquid crystal capacitor Clc1 is charged with a first pixel voltage corresponding to a level difference between the divided voltage and the common voltage Vcom. The arrangement of a liquid crystal director included in the liquid crystal layer of the display panel DP is changed according to the amount of charge charged in the first liquid crystal capacitor Clc1. Light incident on the liquid crystal layer is transmitted or blocked according to the arrangement of the liquid crystal director. The first storage capacitor Cst1 is connected in parallel to the first liquid crystal capacitor Clc1 to maintain the arrangement of the liquid crystal director for a predetermined interval.

The data voltage of the data line DL is provided to the second sub-pixel PX S2 when the second transistor TR2 is turned on.

The second liquid crystal capacitor Clc2 is charged with a second pixel voltage corresponding to a level difference between the data voltage of the data line DL and the common voltage Vcom. The arrangement of the liquid crystal director included in the liquid crystal layer of the display panel DP is changed according to the amount of charge charged in the second liquid crystal capacitor Clc2. Light incident on the liquid crystal layer is transmitted or blocked according to the arrangement of the liquid crystal director. The second storage capacitor Cst2 is connected in parallel to the second liquid crystal capacitor Clc2 to maintain the arrangement of the liquid crystal director for a predetermined interval.

The first pixel voltage charged in the first liquid crystal capacitor Clc1 and the second pixel voltage charged in the second liquid crystal capacitor Clc2 may be different from each other according to the voltage division by the second transistor TR2. In this case, the first pixel voltage may be smaller than the second pixel voltage. When the first and second pixel voltages are different, the gray level displayed in the first sub-pixel PX-S 1 is different from the gray level displayed in the second sub-pixel PX-S2.

In FIG. 4, a first graph G_S1 indicates the transmittance according to the data voltage input to the first sub pixel PX_S1, and the second graph G_S2 indicates the transmittance according to the data voltage input to the second sub pixel PX_S2. Here, when the transmittance is high, the gray level is high, and when the transmittance is low, the gray level is low. For example, when the same data voltage of 4.5V is input to the first and second sub-pixels PX_S1 and PX_S2, an input voltage (e.g., the data voltage) is divided in the first sub-pixel PX_S1 so that the gray level of the first sub-pixel PX_S1 is lower than the gray level of the second sub-pixel PX_S2.

As shown in FIG. 4, even when the same data voltage is applied, the first sub-pixel PX_S1 may display a relatively low gray level while the second sub-pixel PX_S2 may display a relatively high gray level. As described above, by displaying images of different gray levels in the first and second sub-pixels PX_S1 and PX_S2, the visibility of the pixel PX may be improved.

The equivalent circuit diagram of the pixel PX shown in FIG. 3 is only illustrative of the inventive concept of the present disclosure, and the present disclosure is not limited thereto. In another embodiment of the inventive concept, the first and second storage capacitors Cst1 and Cst2 may be omitted.

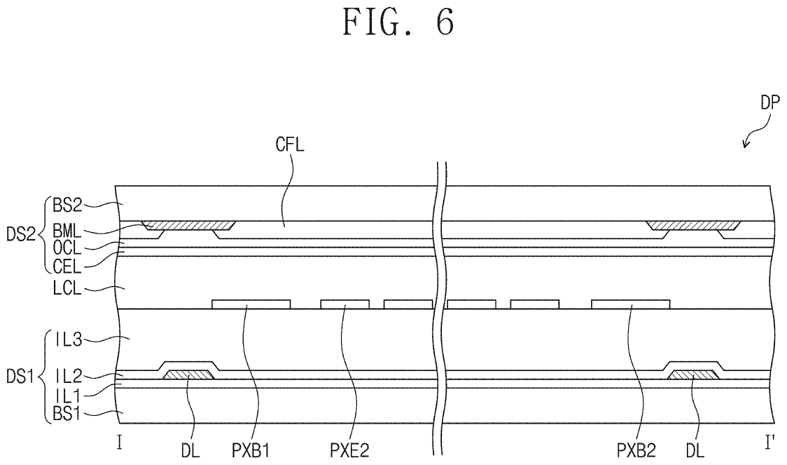

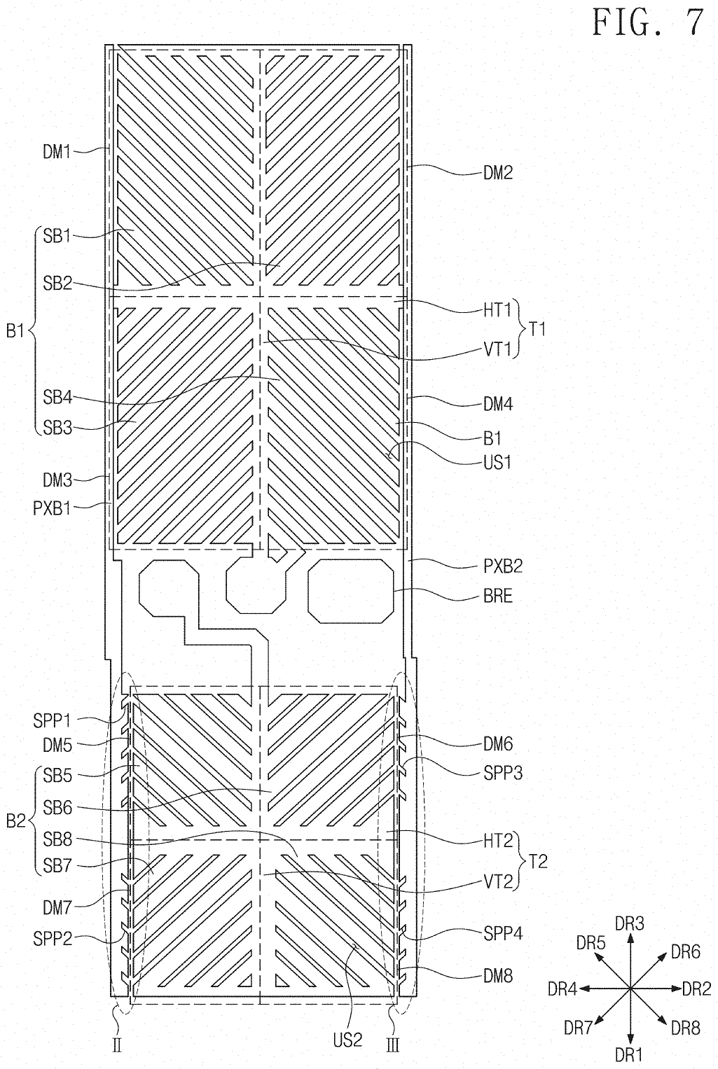

FIG. 5 is a plan view showing a layout of pixels according to an embodiment of the present disclosure, and FIG. 6 is a sectional view taken along line I-I′ shown in FIG. 5.

Referring to FIG. 3 and FIG. 5, each of the plurality of pixels PX may include a first pixel electrode PXE1 disposed in a first pixel area PXA1 and a second pixel electrode PXE2 disposed in a second pixel area PXA2. The second pixel area PXA2 may be disposed adjacent to the first pixel area PXA1 in the first direction DR1. Here, the first pixel electrode PXE1 is defined as the first electrode of the first liquid crystal capacitor Clc1, and the second pixel electrode PXE2 is defined as the first electrode of the second liquid crystal capacitor Clc2.

Each of the plurality of pixels PX may further include a first pixel circuit PXC1 connected to the first pixel electrode PXE1 and a second pixel circuit PXC2 connected to the second pixel electrode PXE2. The first pixel circuit PXC1 may include the first transistor TR1 and the second transistor TR2. The first pixel circuit PXC1 may further include the first storage capacitor Cst1. The second pixel circuit PXC2 may include the third transistor TR3. The second pixel circuit PXC2 may further include the second storage capacitor Cst2.

The first transistor TR1 includes a first control electrode, a first input electrode IE1, and a first output electrode OE1. Each pixel PX further includes a gate electrode portion GEP branching from the gate line GL. A first portion of the gate electrode portion GEP may be used as the first control electrode of the first transistor TR1. The first input electrode IE1 is electrically connected to the data line DL and receives the data voltage. The first input electrode IE1 may branch from the data line DL.

Each pixel PX further includes a first storage electrode STE1 extending from the first output electrode OE1 of the first transistor TR1 and facing a storage line STL. The storage line STL corresponds to a line in which the storage voltage Vcst is supplied, and the first storage electrode STE1 faces the storage line STL to form the first storage capacitor Cst1.

In addition, the first storage electrode STE1 overlaps the first pixel electrode PXE1 and is electrically connected to the first pixel electrode PXE1 through a first contact hole CNT1. Since the first storage electrode STE1 extends from the first output electrode OE1, the first output electrode OE1 is electrically connected to the first pixel electrode PXE1 through the first storage electrode STE1 and the first contact hole CNT1.

The second transistor TR2 includes a second control electrode, a second input electrode IE2, and a second output electrode OE2. A second portion of the gate electrode portion GEP may be used as the second control electrode of the second transistor TR2. The second input electrode IE2 is electrically connected to the storage line STL, and the second output electrode OE2 is electrically connected to the first output electrode OE1 of the first transistor TR1. The second input electrode IE2 of the second transistor TR2 overlaps the storage line STL to further include a bridge electrode BRE for electrically connecting the second input electrode IE2 to the storage line STL. The bridge electrode BRE is connected to the second input electrode IE2 through a first bridge hole BRH1 and connected to the storage line STL through a second bridge hole BRH2. Accordingly, the second input electrode IE2 is electrically connected to the storage line STL through the bridge electrode BRE to receive the storage voltage Vcst.

In FIG. 5, as an example of the inventive concept, the first output electrode OE1 of the first transistor TR1 and the second output electrode OE2 of the second transistor TR2 are shown to be integrally formed, but the inventive concept of the present disclosure is not limited thereto.

In addition, the second transistor TR2 may further include a floating electrode FE. The floating electrode FE is provided between the second output electrode OE2 and the second input electrode IE2 above the second control electrode. The floating electrode FE may be provided to increase a channel length of the second transistor TR2, but may be omitted depending on a desired size and layout of the second transistor TR2.

The third transistor TR3 includes a third control electrode, a third input electrode IE3, and a third output electrode OE3. A third portion of the gate electrode portion GEP may be used as the third control electrode of the third transistor TR3. The third input electrode IE3 is electrically connected to the data line DL and receives the data voltage. The third input electrode IE3 may branch from the data line DL. In FIG. 5, the first and third input electrodes IE1 and IE3 are shown to be integrally formed. However, the inventive concept of the present disclosure is not limited thereto.

Each pixel PX further includes a second storage electrode STE2 extending from the third output electrode OE3 of the third transistor TR3 and facing the storage line STL. The second storage electrode STE2 faces the storage line STL to form the second storage capacitor Cst2.

In addition, the second storage electrode STE2 overlaps the second pixel electrode PXE2 and is electrically connected to the second pixel electrode PXE2 through a second contact hole CNT2. Since the second storage electrode STE2 extends from the third output electrode OE3, the third output electrode OE3 is electrically connected to the second pixel electrode PXE2 through the second storage electrode STE2 and the second contact hole CNT2.

Referring to FIG. 5 and FIG. 6, the display panel DP according to an embodiment of the inventive concept includes the first substrate DS1, the second substrate DS2 facing the first substrate DS1, and a liquid crystal layer LCL disposed between the first substrate DS1 and the second substrate DS2.

The first substrate DS1 includes a first base substrate BS1, the plurality of gate lines GL, the plurality of data lines DL, the plurality of storage lines STL, a first insulation layer IL1 a second insulation layer IL2, a third insulation layer IL3, and the plurality of pixels PX.

The first base substrate BS1 may be a glass substrate or a plastic substrate having light transmission and flexible characteristics. A plurality of pixel areas are defined by the plurality of gate lines GL and the plurality of data lines DL, and in the plurality of pixel areas, the plurality of pixels PX are respectively disposed. Here, the plurality of data lines DL extends in the first direction DR1, the plurality of gate lines GL extends in the second direction DR2, and the plurality of storage lines STL may extend in the second direction in parallel with the gate lines GL.

The plurality of gate lines GL, the gate electrode portion GEP, and the plurality of storage lines STL are disposed on a surface of the first base substrate BS1 that faces the second substrate DS2. The gate lines GL, the gate electrode portion GEP, and the storage lines STL may include a metal such as aluminum (Al), silver (Ag), copper (Cu), molybdenum (Mo), chrome (Cr), tantalum (Ta), titanium (Ti), or an alloy thereof. The gate lines GL, the gate electrode portion GEP, and the storage lines STL may include a multilayer structure, for example, a structure including a titanium layer and a copper layer.

Although not shown in the drawings, control electrodes of the first to third transistors TR1 to TR3 may be formed on the surface of the first base substrate BS1. The control electrodes may branch from a corresponding gate line among the plurality of gate lines GL.

The first insulation layer IL1 for covering the gate lines GL, the gate electrode portion GEP, and the storage line STL are further disposed on the surface of the first base substrate BS1. The first insulation layer IL1 may include at least one of an inorganic material and an organic material. The inorganic material may be, for example, any one of silicon nitride or silicon oxide. The first insulating layer IL1 may have a multilayer structure in which a plurality of inorganic layers are sequentially laminated. The plurality of inorganic layers may be made of different inorganic materials.

The plurality of data lines DL are disposed on the first insulation layer IL1. The plurality of data lines DL extends in the first direction DR1 and disposed to be spaced apart from each other in the second direction DR2. Between two data lines DL that are adjacent to each other, the first pixel electrode PXE1, the second pixel electrode PXE2, the first pixel circuit PXC1, and the second pixel circuit PXC2 are disposed.

Although not shown in the drawings, the first to third input electrodes IE1, IE2, and IE3, and the first to third output electrodes OE1, OE2, and OE3 are further disposed on the first insulation layer IL1. On the first insulation layer IL1 active layers of the first to third transistors TR1, TR2 and TR3 may be further disposed. The active layers may include a semiconductor layer (not shown) and an ohmic contact layer (not shown). The semiconductor layer may include any one of an amorphous silicon, a polysilicon, and a metal oxide semiconductor.

The second insulation layer IL2 and the third insulation layer IL3 for covering the plurality of data lines DL are sequentially disposed on the first insulation layer IL1. The second insulation layer IL2 may include an inorganic material, and the third insulation layer IL3 may include an organic material. The third insulation layer IL3 may provide a flat surface.

The first and second pixel electrodes PXE1 and PXE2 are disposed on the third insulation layer IL3. The first pixel electrode PXE1 is electrically connected to the first output electrode OE1 of the first transistor TR1, and the second pixel electrode PXE2 is electrically connected to the third output electrode OE3 of the third transistor TR3. On the second and third insulation layers IL2 and IL3, the first and second contact holes CNT1 and CNT2, and the first and second bridge holes BRH1 and BRH2 may be formed. The first pixel electrode PXE1 is connected to the first storage electrode STE1 through the first contact hole CNT1 and is electrically connected to the first output electrode OE1 of the first transistor TR1. The second pixel electrode PXE2 is connected to the second storage electrode STE2 through the second contact hole CNT2 and is electrically connected to the third output electrode OE3 of the third transistor TR3.

The second substrate DS2 includes a second base substrate BS2, a black matrix layer BML, a color filter layer CFL, an overcoating layer OCL, and a common electrode layer CEL. The second base substrate BS2 is disposed to face the first base substrate BS1. The second base substrate BS2 may be a glass substrate or a plastic substrate having light transmission and flexible characteristics.

The black matrix layer BML made of an organic material or a metal material having light blocking characteristics is disposed on the second base substrate BS2. The black matrix layer BML may be disposed to correspond to a non-pixel area excluding the first and second pixel areas PXA1 and PXA2 of the first substrate DS1. The first and second pixel electrodes PXE1 and PXE2 are respectively disposed in the first and second pixel areas PXA1 and PXA2 to substantially control alignment of the liquid crystal molecules included in the liquid crystal layer.

The black matrix layer BML is provided to block the light leakage in the non-pixel area.

The color filter layer CFL may be correspond to the first and second pixel areas PXA1 and PXA2 and may partially overlap the black matrix layer BML. The color filter layer CFL may include red, green, and blue color filters. In FIG. 6, a structure in which the color filter layer CFL is provided on the second substrate DS2 is shown. However, the inventive concept of the present disclosure is not limited thereto, and the color filter layer CFL may be provided on the first substrate DS1.

The overcoating layer OCL is provided to cover the black matrix layer BML and the color filter layer CFL. The overcoating layer OCL provides a flat surface to remove a step difference between the black matrix layer BML and the color filter layer CFL. The common electrode layer CEL is provided on the overcoat layer OCL. The common electrode layer CEL may include a transparent electrode material.

The liquid crystal layer LCL is interposed between the first substrate DS1 and the second substrate DS2. The first liquid crystal capacitor Clc1 is formed by the common electrode layer CEL, the liquid crystal layer LCL, and the first pixel electrode PXE1. The second liquid crystal capacitor Clc2 is formed by the common electrode layer CEL, the liquid crystal layer LCL, and the second pixel electrode PXE2.

When the first to third transistors TR1, TR2, and TR3 are turned on, the first liquid crystal capacitor Clc1 is charged with the first pixel voltage, and the second liquid crystal capacitor Clc2 is charged with the second pixel voltage. The first pixel voltage may be lower than the second pixel voltage according to the voltage division by the second transistor TR2. Since the common voltage Vcom (shown in FIG. 3) is applied to the common electrode layer CEL that is commonly connected to the first and second liquid crystal capacitors Clc1 and Clc2, the voltages applied to the first and second pixel electrodes PXE1 and PXE2 become substantially different from each other. Accordingly, for convenience of explanation, the voltage of the first pixel electrode PXE1 is referred to as the first pixel voltage, and the voltage of the second pixel electrode PXE2 is referred to as the second pixel voltage.

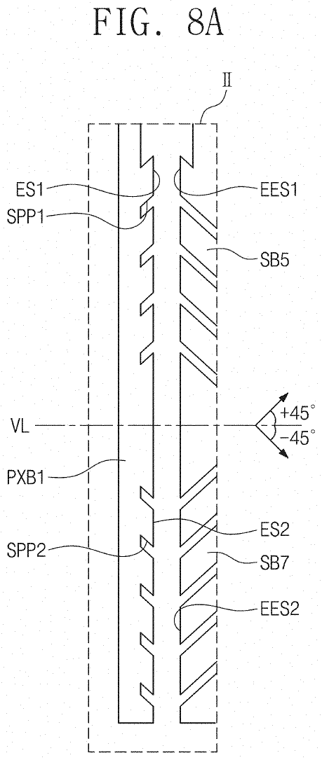

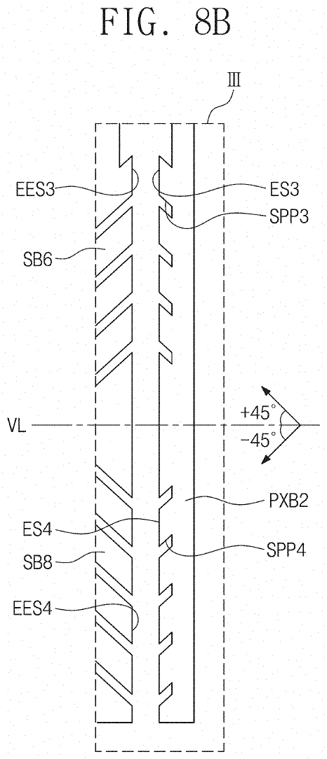

FIG. 7 is a plan view showing a pixel electrode layer shown in FIG. 5, and FIG. 8A and FIG. 8B are enlarged views of the portions II and III of FIG. 7.

Referring to FIG. 5, FIG. 6, FIG. 7, FIG. 8A, and FIG. 8B, the first pixel electrode PXE1 includes a first trunk T1 for dividing the first pixel area PXA1 into a plurality of domains, and a plurality of first branches B1 radially extending from the first trunk T1. The first trunk T1 may include a first vertical trunk VT1 extending in the first direction DR1 and a first horizontal trunk HT1 extending in the second direction DR2. The first pixel area PXA1 may be divided into four domains by the first vertical trunk VT1 and the first horizontal trunk HT1 of the first trunk T1 that cross each other.

The plurality of first branches B1 extends parallel to each other in each of the domains partitioned by the first trunk T1, and are arranged to be spaced apart from each other. As an example of the inventive concept, the first branches B1 may extend in a direction at approximately 45° with respect to the first vertical trunk VT1 and the first horizontal trunk HT1 of the first trunk T1. The first branches B1 adjacent to each other may be spaced apart by a distance in the order of a micrometer to form a plurality of first fine slits US1. The liquid crystal molecules of the liquid crystal layer LCL may be pre-tilted in different directions in each domain by the plurality of first fine slits US1.

As an example of the inventive concept, the first pixel area PXA1 is divided into first to fourth domains DM1 to DM4 by the first vertical trunk VT1 and the first horizontal trunk HT1 of the first trunk T1. The first branches B1 may include first to fourth sub-branches SB1 to SB4 respectively disposed in the first to fourth domains DM1 to DM4.

The first sub-branch SB1 extends in a fifth direction DRS corresponding to a vector sum of the third direction DR3 that is opposite to the first direction DR1 and the fourth direction DR4 that is opposite to the second direction DR2 in the first domain DM1. The second sub-branch SB2 extends in a sixth direction DR6 corresponding to a vector sum of the third direction DR3 and the second direction DR2 in the second domain DM2. The third sub-branch SB3 extends in a seventh direction DR7 corresponding to a vector sum of the fourth direction DR4 and the first direction DR1 in the third domain DM3. The fourth sub-branch SB4 extends in an eighth direction DR8 corresponding to a vector sum of the first direction DR1 and the second direction DR2 in the fourth domain DM4.

The pixel PX according to the inventive concept further includes a pixel electrode bar PXB. The pixel electrode bar PXB branches from the first pixel electrode PXE1 and extends in the first direction DR1 and is disposed adjacent to the first and second pixel electrodes PXE1 and PXE2. The pixel electrode bar PXB may be formed integrally with the first pixel electrode PXE1 and is electrically connected to the first pixel electrode PXE1. Accordingly, the pixel electrode bar PXB receives the first pixel voltage through the first pixel electrode PXE1.

The pixel electrode bar PXB may branch from the first trunk T1. In one embodiment, the pixel electrode bar PXB may branch from the first horizontal trunk HT1 of the first trunk T1. As an example of the inventive concept, the pixel electrode bar PXB may include a first pixel electrode bar PXB1 branching from a first end of the first horizontal trunk HT1, and a second pixel electrode bar PXB2 branching from a second end of the first horizontal trunk HT1.

Each of the first and second pixel electrode bars PXB1 and PXB2 may overlap the data line DL. Each of the first and second pixel electrode bars PXB1 and PXB2 may be disposed in the non-pixel area.

As shown in FIGS. 3, 4, and 5, the first pixel electrode PXE1 maintains the black gray level in a low voltage range (hereinafter, a first voltage range VR1). That is, when a data voltage in the first voltage range VR1 is input to the first pixel electrode PXE1, the first pixel voltage charged to the first liquid crystal capacitor Clc1 may be maintained at approximately 0V. That is, the first pixel electrode PXE1 may have a voltage level substantially the same as that of the common voltage Vcom of the common electrode layer CEL.

As an example of the inventive concept, the first voltage range VR1 may be from 0V to 3V. However, it is understood that the upper limit of the first voltage range VR1 may vary without deviating from the scope of the present disclosure.

Since the first and second pixel electrode bars PXB1 and PXB2 are electrically connected to the first pixel electrode PXE1, the first and second pixel electrode bars PXB1 and PXB2 may also have substantially the same voltage level as that of the common voltage Vcom of the common electrode layer CEL in the first voltage range VR1. Therefore, a zero-electric field region may be formed between the first pixel electrode bar PXB1 and the common electrode layer CEL and between the second pixel electrode bar PXB2 and the common electrode layer CEL. Thereby, the liquid crystal molecules of the liquid crystal layer LCL between the first pixel electrode bar PXB1 and the common electrode layer CEL and between the second pixel electrode bar PXB2 and the common electrode layer CEL may be vertically arranged to block light. That is, in the first voltage range VR1, the first and second pixel electrode bars PXB1 and PXB2 may serve as a light blocking layer.

Accordingly, the light leakage that may occur in an edge portion of the first and second pixel areas PXE1 and PXE2 at a low gray level may be reduced by the first and second pixel electrode bars PXB1 and PXB2.

The second pixel electrode PXE2 includes a second trunk T2 for dividing the second pixel area PXA2 into a plurality of domains, and a plurality of second branches B2 radially extending from the second trunk T2. The second trunk T2 may include a second vertical trunk VT2 extending in the first direction DR1 and a second horizontal trunk HT2 extending in the second direction DR2. The second pixel area PXA2 may be divided into four domains by the second vertical trunk VT2 and the second horizontal trunk HT2 of the second trunk T2 that cross each other.

The plurality of second branches B2 extends parallel to each other in a domain partitioned by the second trunk T2, and are arranged to be spaced apart from each other. As an example of the inventive concept, the second branches B2 may extend in a direction at approximately 45° with respect to the second vertical trunk VT2 and the second horizontal trunk HT2 of the second trunk T2. The second branches B2 adjacent to each other may be spaced apart by a distance in the order of a micrometer to form a plurality of second fine slits US2. The liquid crystal molecules of the liquid crystal layer LCL may be pre-tilted in different directions by each domain by the plurality of second fine slits US2.

As an example of the inventive concept, the second pixel area PXA2 is divided into fifth to eighth domains DM5 to DM8 by the second vertical trunk VT2 and the second horizontal trunk HT2 of the second trunk T2. The second branches B2 may include fifth to eighth sub-branches SB5 to SB8 respectively disposed in the fifth to eighth domains DM5 to DM8.

The fifth sub-branch SB5 extends in the fifth direction DRS in the fifth domain DM5, and the sixth sub-branch SB6 extends in the sixth direction DR6 in the sixth domain DM6. The fifth direction DRS is inclined at an angle of +45° (45° clockwise) with respect to the fourth direction DR4, and the sixth direction DR6 is inclined at an angle of +45° (45° counter-clockwise) with respect to the second direction DR2.

The seventh sub-branch SB7 extends in the seventh direction DR7 in the seventh domain DM7, and the eighth sub-branch SB8 extends in the eighth direction DR8 in the eighth domain DM8. The seventh direction DR7 is inclined at an angle of −45° with respect to the fourth direction DR4, and the eighth direction DR8 is inclined at an angle of −45° with respect to the second direction DR2.

Referring to FIG. 7, FIG. 8A, and FIG. 8B, each pixel PX may further include a plurality of protrusions protruding from the pixel electrode bar PXB.

The plurality of protrusions may include first protrusions and second protrusions. As an example of the inventive concept, the first protrusions include first and second sub-protrusions SPP1 and SPP2 protruding from the first pixel electrode bar PXB1, and the second protrusions include third and fourth sub-protrusions SPP3 and SPP4 protruding from the second pixel electrode bar PXB2.

Referring to FIG. 8A, the first sub-protrusions SPP1 are adjacent to the fifth sub-branches SB5 of the second pixel electrode PXE2, and protrude from the first pixel electrode bar PXB1 toward the fifth sub-branches SB5. The second sub-protrusions SPP2 are adjacent to the seventh sub-branches SB7 of the second pixel electrode PXE2, and protrude from the first pixel electrode bar PXB1 toward the seventh sub-branches SB7. Each of the first sub-protrusions SPP1 may obliquely protrude from the first pixel electrode bar PXB1 at an angle of +45° with respect to a virtual line VL that is parallel to the second horizontal trunk HT2, and each of the second sub-protrusions SPP2 may obliquely protrude from the first pixel electrode bar PXB1 at an angle of −45° with respect to the virtual line VL.

The inclination angle of each of the first and second sub-protrusions SPP1 and SPP2 may vary according to the inclination angle of the fifth and seventh sub-branches SB5 and SB7. As an example of the inventive concept, the inclination angle of each of the first and second sub-protrusions SPP1 and SPP2 may correspond to the inclination angle of the fifth and seventh sub-branches SB5 and SB7.

An end surface ES1 of each of the first sub-protrusions SPP1 is disposed to face an end surface EES1 of each of the fifth sub-branches SB5, and an end surface ES2 of each of the second sub-protrusions SPP2 is disposed to face an end surface EES2 of each of the seventh sub-branches SB7. That is, the first and second sub-protrusions SPP1 and SPP2 may be disposed to be aligned with the fifth and seventh sub-branches SB5 and SB7.

Referring to FIG. 8B, the third sub-protrusions SPP3 are adjacent to the sixth sub-branches SB6 of the second pixel electrode PXE2, and protrude from the second pixel electrode bar PXB2 toward the sixth sub-branches SB6. The fourth sub-protrusions SPP4 are adjacent to the eighth sub-branches SB8 of the second pixel electrode PXE2, and protrude from the second pixel electrode bar PXB2 toward the eighth sub-branches SB8. The third sub-protrusions SPP3 may obliquely protrude from the second pixel electrode bar PXB2 at an angle of +45° with respect to the virtual line VL that is parallel to the second horizontal trunk HT2, and the fourth sub-protrusions SPP4 may obliquely protrude from the second pixel electrode bar PXB2 at an angle of −45° with respect to the virtual line VL.

The inclination angle of each of the third and fourth sub-protrusions SPP3 and SPP4 may vary according to the inclination angle of the sixth and eighth sub-branches SB6 and SB8. As an example of the inventive concept, the inclination angle of each of the third and fourth sub-protrusions SPP3 and SPP4 may correspond to the inclination angle of the sixth and eight sub-branches SB6 and SB8.

An end surface ES3 of each of the third sub-protrusions SPP3 is disposed to face an end surface EES3 of each of the sixth sub-branches SB6, and an end surface ES4 of each of the fourth sub-protrusions SPP4 is disposed to face an end surface EES4 of each of the eighth sub-branches SB8. That is, the third and fourth sub-protrusions SPP3 and SPP4 may be disposed to be aligned with the sixth and eighth sub-branches SB6 and SB8.

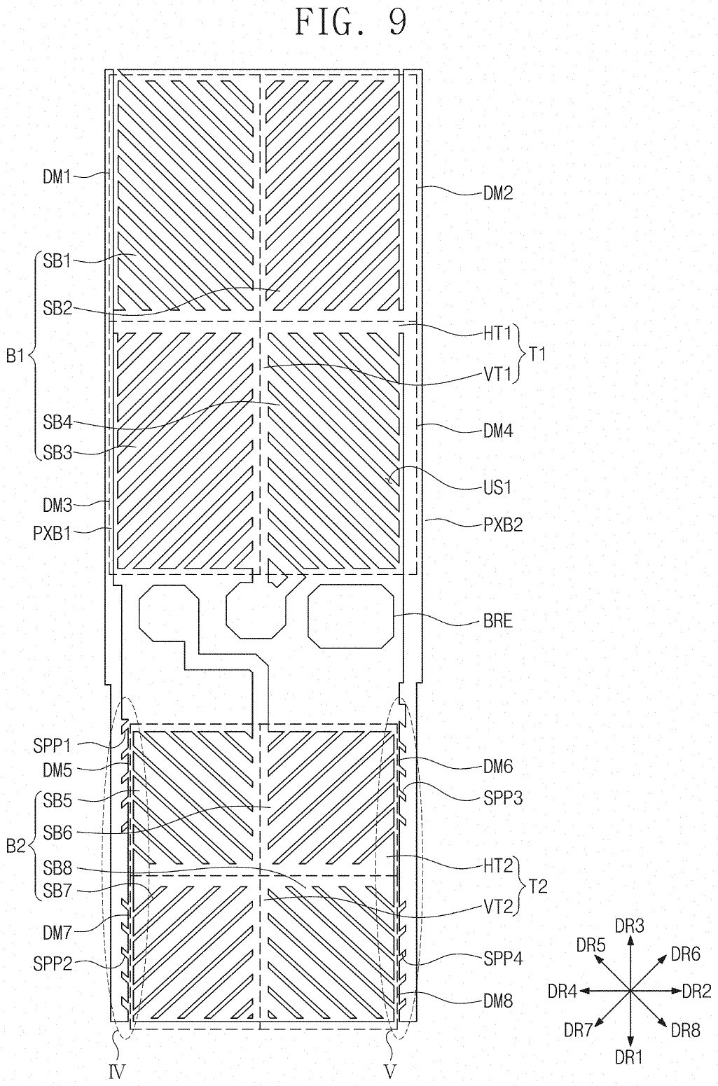

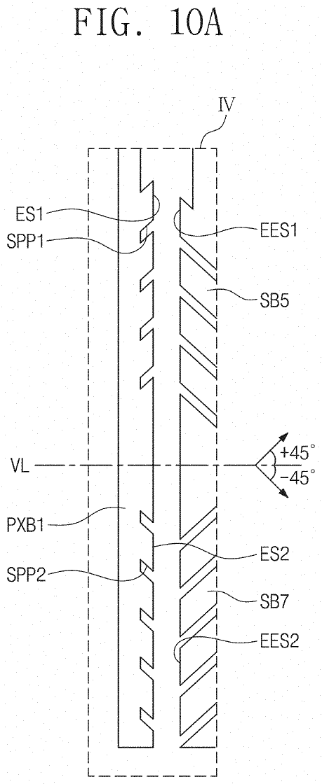

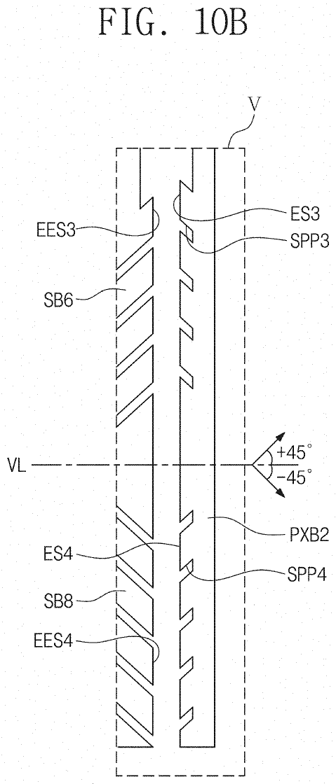

FIG. 9 is a plan view showing a pixel electrode bar according to another embodiment of the present disclosure, and FIGS. 10A and 10B are enlarged views of each of the portions IV and V of FIG. 9.

Referring to FIG. 9, FIG. 10A, and FIG. 10B, the first and second sub-protrusions SPP1 and SPP2 of the first pixel electrode bar PXB1 are shifted in one of the first and third directions DR1 and DR3. Accordingly, the first and second sub-protrusions SPP1 and SPP2 are disposed to be staggered with the fifth and seventh sub-branches SB5 and SB7, respectively.

Referring to FIG. 10A, the end surface ES1 of each of the first sub-protrusions SPP1 is disposed to partially face the end surface EES1 of each of the fifth sub-branches SB5, and the end surface ES2 of each of the second sub-protrusions SPP2 is disposed to partially face the end surface EES2 of each of the seventh sub-branches SB7. That is, the first sub-protrusions SPP1 may be disposed to be staggered with the fifth sub-branches SB5, and the second sub-protrusions SPP2 may be disposed to be staggered with the seventh sub-branches SB7.

Referring to FIG. 10B, the third and fourth sub-protrusions SPP3 and SPP4 of the second pixel electrode bar PXB2 are shifted in one of the first and third directions DR1 and DR3. Accordingly, the third and fourth sub-protrusions SPP3 and SPP4 are disposed to be staggered with the sixth and eighth sub-branches SB6 and SB8, respectively.

The end surface ES3 of each of the third sub-protrusions SPP3 is disposed to partially face the end surface EES3 of each of the sixth sub-branches SB6, and the end surface ES4 of each of the fourth sub-protrusions SPP4 is disposed to partially face the end surface EES4 of each of the eighth sub-branches SB8. That is, the third sub-protrusions SPP3 may be disposed to be staggered with the sixth sub-branches SB6, and the fourth sub-protrusions SPP4 may be disposed to be staggered with the eighth sub-branches SB8.

In FIG. 9, FIG. 10A, and FIG. 10B, a structure in which the first to fourth sub-protrusions SPP1 to SPP4 are shifted in the third direction DR3 is shown. However, the inventive concept of the present disclosure is not limited thereto. In one embodiment, the first and second sub-protrusions SPP1 and SPP2 may be shifted in the first direction DR1, and the third and fourth sub-protrusions SPP3 and SPP4 may be shifted in the third direction DR3. In another embodiment, the first and second sub-protrusions SPP1 and SPP2 may be shifted in the third direction DR3, and the third and fourth sub-protrusions SPP3 and SPP4 may be shifted in the first direction DR1. In yet another embodiment, the first to fourth sub-protrusions SPP1 to SPP4 may be shifted in the first direction DR1.

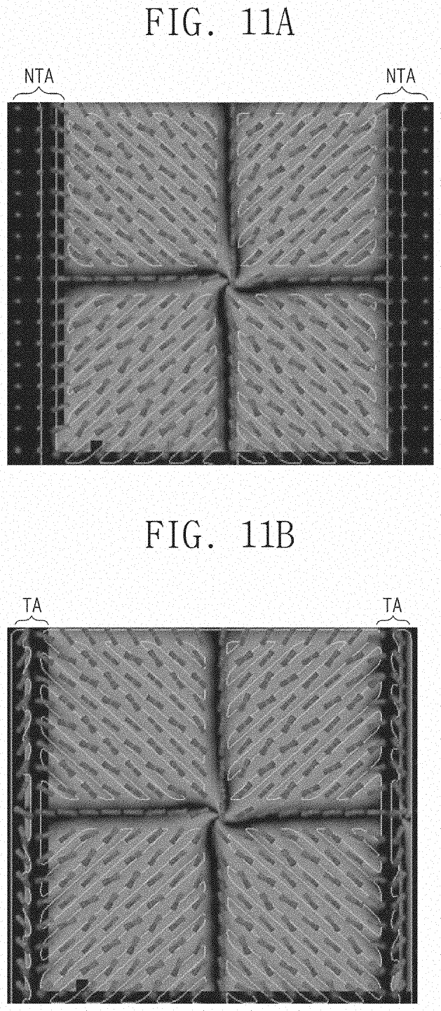

FIG. 11A is a view showing a simulation result of a liquid crystal array in a structure in which a shielding electrode is disposed as a comparative example, and FIG. 11B is a view showing a simulation result of a liquid crystal array in a structure in which a pixel electrode bar according to the present disclosure is disposed.

Referring to FIG. 11A, a shielding electrode (not shown) is disposed adjacent to the second pixel electrode PXE2. The common voltage Vcom is applied to the shielding electrode to form a zero-electric field region between the shielding electrode and the common electrode layer CEL. Accordingly, the shielding electrode may prevent light leakage that may occur due to the misalignment of liquid crystal molecules in the liquid crystal layer LCL in a fringe portion of the non-pixel area. That is, an area in which the shielding electrode is formed serves as a non-transmissive region NTA since the liquid crystal molecules in the liquid crystal layer LCL are aligned to block light in the zero-electric field region.

Referring to FIG. 4 and FIG. 11B, the pixel electrode bar PXB is disposed adjacent to the second pixel electrode PXE2 and electrically connected to the first pixel electrode PXE1. Accordingly, in the first voltage range VR1 (a low voltage range, for example, 0V to 3V), the pixel electrode bar PXB receives a voltage that corresponds to the common voltage Vcom, and a zero-electric field region is formed in a region in which the pixel electrode bar PXB is formed Therefore, the region in which the pixel electrode bar PXB is formed may serve as a non-transmissive region in the first voltage range VR1.

However, in a second voltage range VR2 (a high voltage range, e.g., higher than 3V) that is higher than the first voltage range VR1, the pixel electrode bar PXB receives a voltage that is different from the common voltage Vcom. Accordingly, a non-zero electric field is formed between the pixel electrode bar PXB and the second pixel electrode PXE2, the liquid crystal molecules in the region in which the pixel electrode bar PXB is formed are aligned based on the non-zero electric field. Therefore, the region in which the pixel electrode bar PXB is formed may serve as a transmissive region in the second voltage range VR2.

Specifically, in an area in which the second branches B2 of the second pixel electrode PXE2 face with the protrusions SPP1 to SPP4 of the pixel electrode bar PXB, the liquid crystal molecules are arranged in a similar manner as in the second pixel area PXA2. Thereby, as the transmissive region of the second sub-pixel PX_S2 extends to the area in which the pixel electrode bar PXB is formed, the transmittance of the second sub-pixel PX_S2 may be improved.

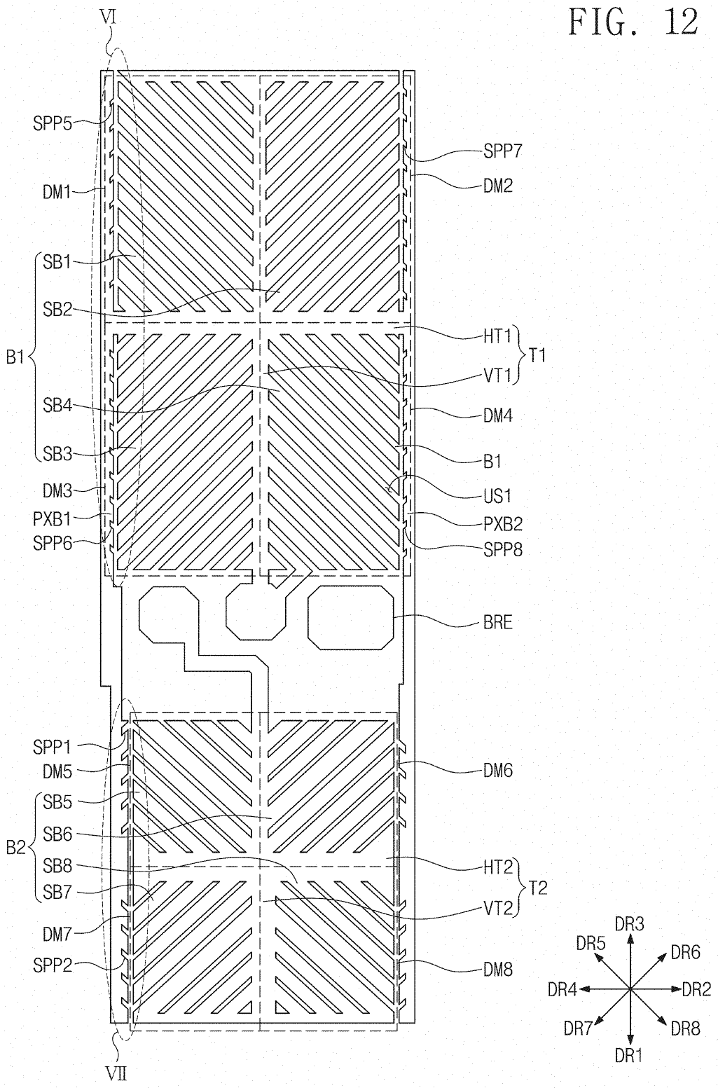

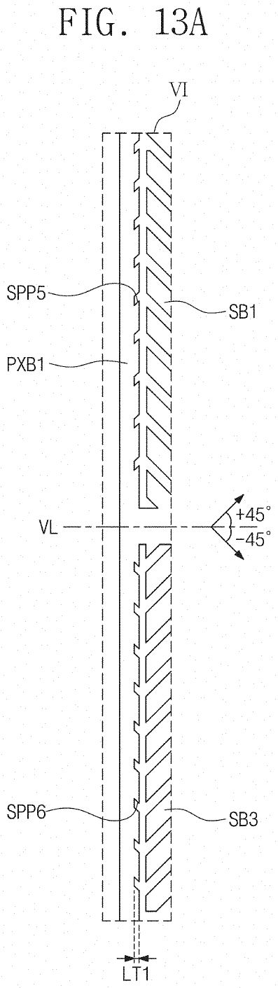

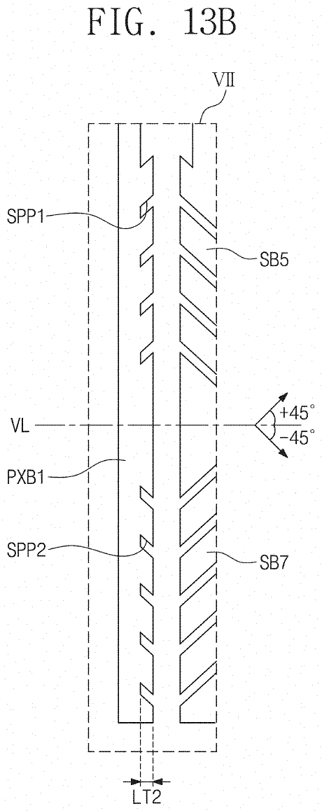

FIG. 12 is a plan view showing a pixel electrode bar according to another embodiment of the present disclosure. FIG. 13A and FIG. 13B are enlarged views of each of the portions VI and VII of FIG. 12.

Referring to FIG. 12, FIG. 13A, and FIG. 13B, the plurality of protrusions may further include third protrusions and fourth protrusions. As an example of the inventive concept, the third protrusions include fifth and sixth sub-protrusions SPP5 and SPP6 protruding from the first pixel electrode bar PXB1, and the fourth protrusions include seventh and eighth sub-protrusions SPP7 and SPP8 protruding from the second pixel electrode bar PXB2.

Referring to FIG. 13A, the fifth sub-protrusions SPP5 are adjacent to the first sub-branches SB1 of the first pixel electrode PXE1, and protrude from the first pixel electrode bar PXB1 toward the firth sub-branches SB1. The sixth sub-protrusions SPP6 are adjacent to the third sub-branches SB3 of the first pixel electrode PXE1, and protrude from the first pixel electrode bar PXB1 toward the third sub-branches SB3. Each of the fifth sub-protrusions SPP5 may obliquely protrude from the first pixel electrode bar PXB1 at an angle of +45° with respect to the virtual line VL that is parallel to the first horizontal trunk HT1, and each of the sixth sub-protrusions SPP6 may obliquely protrude from the first pixel electrode bar PXB1 at an angle of −45° with respect to the virtual line VL.

The seventh sub-protrusions SPP7 are adjacent to the second sub-branches SB2 of the first pixel electrode PXE1, and protrude from the second pixel electrode bar PXB2 toward the second sub-branches SB2, and the eighth sub-protrusions SPP8 are adjacent to the fourth sub-branches SB4 of the first pixel electrode PXE1, and protrude from the second pixel electrode bar PXB2 toward the fourth sub-branches SB4. The seventh sub-protrusions SPP7 may obliquely protrude from the second pixel electrode bar PXB2 at an angle of +45° with respect to the virtual line VL that is parallel to the first horizontal trunk HT1, and the eighth sub-protrusions SPP8 may obliquely protrude from the second pixel electrode bar PXB2 at an angle of −45° with respect to the virtual line VL.

According to one embodiment, the protrusion length LT1 of each of the fifth and sixth sub-protrusions SPP5 and SPP6 may be smaller than the protrusion length LT2 of each of the first and second sub-protrusions SPP1 and SPP2. In addition, the protrusion length of each of the seventh and eighth sub-protrusions SPP7 and SPP8 may be smaller than the protrusion length LT1 of each of the third and fourth sub-protrusions SPP3 and SPP4.

According to one embodiment, the first pixel area PXA1 has an area of approximately two times greater than that of the second pixel area PXA2. In this case, a space for forming the fifth to eighth sub-protrusions SPP5 to SPP8 in the first pixel area PXA1 may be smaller than the second pixel area PXA2 based on a design of the pixel structure. In this case, the fifth to eighth sub-protrusions SPP5 to SPP8 formed in the first pixel area PXA1 may be formed smaller than the first to fourth sub-protrusions SPP1 to SPP4 formed in the second pixel area PXA2.

According to the display apparatus according to an embodiment of the present disclosure, in a structure in which each pixel includes first and second sub-pixels, a pixel electrode bar that is electrically connected to a first pixel electrode may extend in parallel with a data line and disposed adjacent to a second pixel electrode.

When a data voltage in a first voltage range is applied, the pixel electrode bar maintains a black gray level and forms a zero-electric field region to serve as a non-transmissive region, and when the data voltage in a second voltage range is applied, the pixel electrode bar forms an electric field with the second pixel electrode to serve as a transmissive region.

Accordingly, the transmittance of the second sub-pixel may be improved, and the visibility of the display apparatus at a low gray level may be improved.

Although the inventive concept has been described with reference to exemplary embodiments, it will be understood by those skilled in the art that various changes in form and details may be made therein without departing from the spirit and scope of the inventive concept.

Accordingly, the technical aspect of the inventive concept of the present disclosure is not intended to be limited to the embodiments set forth in the detailed description of the specification, but is intended to be defined in the appended claims.

What is claimed is:

1. A display apparatus comprising:
a data line extending in a first direction;
a gate line extending in a second direction;
a first pixel circuit connected to the data line and the gate line;
a first pixel electrode connected to the first pixel circuit to receive a first pixel voltage and disposed in a first pixel area;
a second pixel circuit connected to the data line and the gate line;
a second pixel electrode connected to the second pixel circuit to receive a second pixel voltage that is higher than the first pixel voltage and disposed in a second pixel area, the second pixel electrode being adjacent to the first pixel electrode in the first direction; and
a pixel electrode bar branching from the first pixel electrode and extending in the first direction and disposed adjacent to the first pixel electrode and the second pixel electrode.

2. The display apparatus of claim 1, wherein the first pixel electrode comprises:
a first trunk including a first horizontal trunk extending in the second direction and a first vertical trunk extending in the first direction to divide the first pixel area into a plurality of domains; and
a plurality of first branches radially extending from the first trunk.

3. The display apparatus of claim 2, wherein the pixel electrode bar extends from the first horizontal trunk that extends in the first direction.

4. The display apparatus of claim 3, wherein the pixel electrode bar comprises:
a first pixel electrode bar extending from a first end of the first horizontal trunk; and
a second pixel electrode bar extending from a second end of the first horizontal trunk.

5. The display apparatus of claim 4, wherein the second pixel electrode comprises:
a second trunk including a second horizontal trunk extending in the second direction and a second vertical trunk extending in the first direction to divide the second pixel area into a plurality of domains; and
a plurality of second branches radially extending from the second trunk.

6. The display apparatus of claim 5 further comprising a plurality of protrusions protruding from a portion of the pixel electrode bar adjacent to the second pixel area toward the plurality of second branches of the second pixel electrode.

7. The display apparatus of claim 6, wherein the plurality of second branches obliquely extends at a first angle from the second trunk, and
the plurality of protrusions obliquely protrudes at a second angle from the pixel electrode bar.

8. The display apparatus of claim 7, wherein absolute magnitudes of the first angle and the second angle are the same.

9. The display apparatus of claim 7, wherein each of the plurality of second branches comprises one or more sub-branches having end surfaces partially facing end surfaces of the plurality of protrusions.

10. The display apparatus of claim 7, wherein each of the plurality of second branches each comprise one or more sub-branches shifted in the first direction or a third direction that is opposite to the first direction from end surfaces of the plurality of protrusions and having end surfaces partially facing the end surfaces of the plurality of protrusions.

11. The display apparatus of claim 5 further comprising: a first protrusion protruding from a first portion of the first pixel electrode bar toward the plurality of second branches of the second pixel electrode; and
a second protrusion protruding from a second portion of the second pixel electrode bar toward the plurality of second branches of the second pixel electrode.

12. The display apparatus of claim 11, wherein the plurality of second branches obliquely extends at a first angle from the second trunk, and
the first protrusion comprises:
a first sub-protrusion obliquely protruding at a second angle with respect to a virtual line that is parallel to the second horizontal trunk; and
a second sub-protrusion obliquely protruding at a third angle with respect to the virtual line.

13. The display apparatus of claim 12, wherein the first sub-protrusion is inclined at a positive angle with respect to the virtual line, and the second sub-protrusion is inclined at a negative angle with respect to the virtual line, and absolute magnitudes of the first angle, the second angle, and the third angle are the same.

14. The display apparatus of claim 11, wherein the plurality of second branches obliquely extends at a first angle from the second trunk, and
the second protrusion comprises:
a third sub-protrusion obliquely protruding at a second angle with respect to a virtual line that is parallel to the second horizontal trunk; and
a fourth sub-protrusion obliquely protruding at a third angle with respect to the virtual line.

15. The display apparatus of claim 14, wherein the third sub-protrusion is inclined at a positive angle with respect to the virtual line, and the fourth sub-protrusion is inclined at a negative angle with respect to the virtual line, and absolute magnitudes of the first angle, the second angle, and the third angle are the same.

16. The display apparatus of claim 11 further comprising:
a third protrusion protruding from a third portion of the first pixel electrode bar toward the plurality of first branches of the first pixel electrode; and
a fourth protrusion protruding from a fourth portion of the second pixel electrode bar toward the plurality of first branches of the first pixel electrode.

17. The display apparatus of claim 16, wherein a protrusion length of each of the third protrusion and the fourth protrusion is smaller than a protrusion length of each of the first protrusion and the second protrusion.

18. The display apparatus of claim 1, wherein the first pixel circuit comprises:
a first transistor including a first control electrode connected to the gate line, a first input electrode connected to the data line, and a first output electrode connected to the first pixel electrode; and
a second transistor including a second control electrode connected to the gate line, a second input electrode receiving a storage voltage, and a second output electrode connected to the first output electrode of the first transistor, and
the second pixel circuit comprises:
a third transistor including a third control electrode connected to the gate line, a third input electrode connected to the data line, and a third output electrode connected to the second pixel electrode.

19. The display apparatus of claim 18, wherein when a data voltage applied to the data line is in a first voltage range, the first pixel voltage maintains a black gray level, and a non-transmissive region is formed in a region in which the pixel electrode bar is formed, and wherein liquid crystal molecules in the non-transmissive region are vertically aligned to block light.

20. The display apparatus of claim 19, wherein when the data voltage is in a second voltage range that is higher than the first voltage range, a transmissive region is formed between the pixel electrode bar and the second pixel electrode, and wherein the liquid crystal molecules in the transmissive region are aligned to transmit light.
